(19) United States
(12) Patent Application Publication
(10) Pub. No.: US 2005/0051845 A1
(43) Pub. Date: Mar. 10, 2005

(54) Semiconductor device and manufacturing method therefor

(75) Inventors: Yoshikazu Nakagawa, Shizuoka (JP); Naoki Izumi, Shizuoka (JP)

Correspondence Address: LEYDIG VOIT & MAYER, LTD, 700 THIRTEENTH ST. NW, SUITE 300, WASHINGTON, DC, 20005-3960, US

(73) Assignee: Semiconductor Leading Edge Technologies, Inc., Tsukuba-shi (JP)

(21) Appl. No.: 10/910,576

(22) Filed: Aug. 4, 2004

(30) Foreign Application Priority Data
Sep. 8, 2003 (JP) 2003-315743

(51) Int. Cl. H01L 21/00

(52) U.S. Cl. 257/351

(57) ABSTRACT

A gate electrode in an NMOS region is one of intrinsic silicon and a material having a work function equivalent to that of intrinsic silicon, and a material having a work function smaller than that of intrinsic silicon. A gate electrode in a PMOS region is one of intrinsic silicon and a material having a work function equivalent to that of intrinsic silicon, and a material having a work function larger than that of intrinsic silicon. Further, a source/drain region in the NMOS region includes a silicide layer of a material having a work function smaller than that of intrinsic silicon, and a source/drain region in the PMOS region includes a silicide layer of a material having a work function larger than that of intrinsic silicon.

### BACKGROUND OF THE INVENTION

1. Field of the Invention

The present invention relates to a semiconductor device and a manufacturing method therefor, and more particularly to a semiconductor device including NMOS (N-channel Metal Oxide Semiconductor) and PMOS (P-channel Metal Oxide Semiconductor) structures and a manufacturing method therefor.

2. Background Art

Conventional MOSFETs (Metal Oxide Semiconductor Field Effect Transistors) generally use polysilicon as their gate electrode material. In the case of dual gate CMOS (Complementary. Metal Oxide Semiconductor) structures, for example, N type polysilicon and P type polysilicon have been used for their NMOS and PMOS regions, respectively.

In recent years, the integration density of semiconductor integrated circuit devices has considerably increased, since the performance of devices such as transistors has been enhanced. Especially, gate insulating films, which are a component of the MOS structure, have become thinner and thinner to accommodate the miniaturization, higher-speed operation, and lower-voltage operation of the transistors. Reducing the thickness of gate insulating films facilitates control of the depletion layer(s) formed within the silicon substrate, resulting in reduced short channel effects in the MOSFETs.

However, if a gate electrode does not have a sufficient carrier concentration, a depletion layer is formed within it when the electric field applied to the gate electrode side is relatively increased due to the reduced thickness of the gate insulating film. This means that a gate electrode formed of polysilicon is likely to suffer the above problem of a depletion layer being formed within it since there is a limit to the amount of impurities which can be injected into polysilicon.

Formation of a depletion layer in a gate electrode increases the effective thickness of the gate insulating film, thereby reducing the current driving capability. Therefore, when a gate insulating film having a reduced film thickness is required, the actual film thickness must be set to a few angstroms less than the required film thickness determined on the assumption that no depletion layer is formed within the gate insulating film. However, considerably reducing the film thickness of a gate insulating film causes the problem of an increased tunneling current, or gate leakage current, attributed to the fact that carries (electrons and holes) directly pass through the gate insulating film. Furthermore, there is another problem in that boron (B) contained in the P type polysilicon as an impurity penetrates through the gate insulating film to reach the channel layer in the semiconductor substrate, affecting the transistor threshold voltage (which may cause each produced device to vary in transistor threshold voltage).

To address this problem, it is considered that a metal having a high melting point may be used as the gate electrode material, instead of polysilicon. This allows reducing the resistance of gate electrodes as well as solving the above problems of a depletion layer being formed in gate electrodes and of boron (B) penetrating through gate insulating films.

However, CMOS transistors using a high melting point metal as their gate electrode material have a high transistor threshold voltage.

For example, the work functions of tungsten (W), cesium (Cs), cobalt (Co), and titanium nitride (TiN) are located near the midgap of the forbidden band of silicon (that is, these materials have work functions nearly equal to that of intrinsic silicon). Since NMOS and PMOS structures using these materials have a work function difference of approximately 0.5 eV, it is difficult to set their transistor threshold voltage to this value or less.

In view of this, it is proposed that the NMOS and PMOS structures may each use a metal having a different work function as their gate electrode material. For example, hafnium (Hf) or zirconium (Zr), whose work function is approximately 4.0 eV, may be used for the NMOS structure, while iridium (Ir) or platinum (Pt), whose work function is approximately 5.2 eV, may be used for the PMOS structure.

To achieve the above arrangement, however, the NMOS and PMOS regions must be formed separately (conventionally they are formed in the same process). Specifically, after covering the PMOS gate insulating film with a dummy film such as a polysilicon film, an NMOS gate electrode material is formed on the entire surface. Then, after removing portions of the NMOS gate electrode material other than that on the NMOS region, the dummy film for PMOS is removed. After that, a PMOS gate electrode material is formed on the entire surface. Lastly, portions of the PMOS gate electrode material other than that on the PMOS region are removed. The above process can form NMOS and PMOS gate electrodes using different metals. However, such a process is very complicated, causing the problem of reduced yield and throughput and hence increased cost.

Japanese Laid-Open Patent Publication No. 2002-237589 proposes another method for providing a low transistor threshold voltage, in which: a tungsten film is used as the gate electrode material; and after covering the PMOS region with a resist film, thorium is ion-implanted in the tungsten film in the NMOS region to produce PMOS and NMOS gate electrodes having different work functions. With this method, however, the following problem arises when the resistance of the source/drain regions is reduced.

With the miniaturization of semiconductor devices, the junction depth of source/drain diffusion layers has tended to decrease. However, the shallower a diffusion layer, the larger its resistance. This means that the influence of the parasitic resistance on the device characteristics can no longer be ignored. To overcome this problem of increased resistance due to a very shallow diffusion layer, a metal silicide layer of titanium (Ti), cobalt (Co), or nickel (Ni) has been formed (in source/drain regions).

Conventionally, a metal silicide layer is formed on both the source/drain regions and the gate electrodes at the same time. When metal is used as the gate electrode material, however, the silicide layer must be formed only in the source/drain regions, complicating the silicide layer forming process.

### SUMMARY OF THE INVENTION

The present invention has been devised in view of the above problems. It is, therefore, an object of the present invention to provide a semiconductor device having a low resistance and a low threshold voltage.

Another object of the present invention is to provide a method for easily manufacturing a semiconductor device having a low resistance and a low threshold voltage.

According to one aspect of the present invention, a semiconductor device comprises an NMOS region including a first gate electrode and a first source/drain region, and a PMOS region including a second gate electrode and a second source/drain region. The first gate electrode in the NMOS region is formed of either intrinsic silicon or a material having a work function equivalent to that of intrinsic silicon, and a material having a work function smaller than that of intrinsic silicon. The second gate electrode in the PMOS region is formed of either intrinsic silicon or a material having a work function equivalent to that of intrinsic silicon, and a material having a work function larger than that of intrinsic silicon.

According to another aspect of the present invention, in a method for manufacturing a semiconductor device, a device separation region is formed in a silicon substrate to define an NMOS region and a PMOS region. A gate insulating film is formed on the silicon substrate. A first material film is formed on the gate insulating film. The first material film is made of either intrinsic silicon or a material having a work function equivalent to that of intrinsic silicon. The first material film is etched to form a gate electrode pattern. A second material film is formed on at least the portion of the first material film in the NMOS region. The second material film is made of a material having a work function smaller than that of intrinsic silicon. Through a heat treatment, the second material film is caued to selectively react with the first material film to form an NMOS gate electrode made up of a reaction film between the first material film and the second material film. An unreacted portion of the second material film is removed. A third material film is formed on at least the portion of the first material film in the PMOS region. The third material film is made of a material having a work function larger than that of intrinsic silicon. Through a heat treatment, the third material film is caused to selectively react with the first material film to form a PMOS gate electrode made up of a reaction film between the first material film and the third material film. An unreacted portion of the third material film is removed.

Other and further objects, features and advantages of the invention will appear more fully from the following description.

### BRIEF DESCRIPTION OF THE DRAWINGS

FIG. 1 is a cross-sectional view of a semiconductor device according to the present invention.

FIG. 2-17 are cross-sectional views illustrating a method for manufacturing a semiconductor device according to the present invention.

### DETAILED DESCRIPTION OF THE PREFERRED EMBODIMENTS

A preferred embodiment of the present invention will be described below in detail with reference to the accompanying drawings.

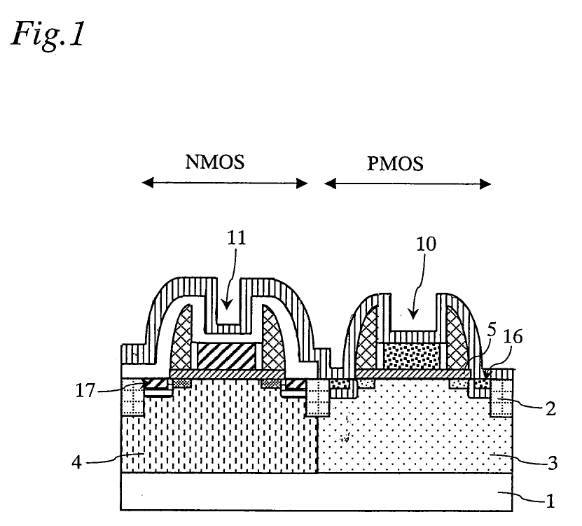

FIG. 1 is a cross-sectional view of a semiconductor device according to an embodiment of the present invention.

As shown in FIG. 1, an N well 3 and a P well 4 separated by device separation regions 2 are formed in a silicon substrate 1. The N well 3 corresponds to the PMOS region, while the P well 4 corresponds to the NMOS region. Gate electrodes 10 and 11 are formed on a gate insulating film 5 formed on the silicon substrate 1. The gate electrode 10 in the PMOS region is formed of either intrinsic silicon or a material having a work function equivalent to that of intrinsic silicon, and a material having a work function larger than that of silicon. The gate electrode 11 in the NMOS region is formed of either intrinsic silicon or a material having a work function equivalent to that of intrinsic silicon, and a material having a work function smaller than that of intrinsic silicon.

Silicide layers are formed in source/drain regions 16 and 17 in the silicon substrate 1. The silicide layer in the PMOS source/drain region 16 is of a material having a work function larger than that of intrinsic silicon, while the silicide layer in the NMOS source/drain region 17 is of a material having a work function smaller than that of intrinsic silicon.

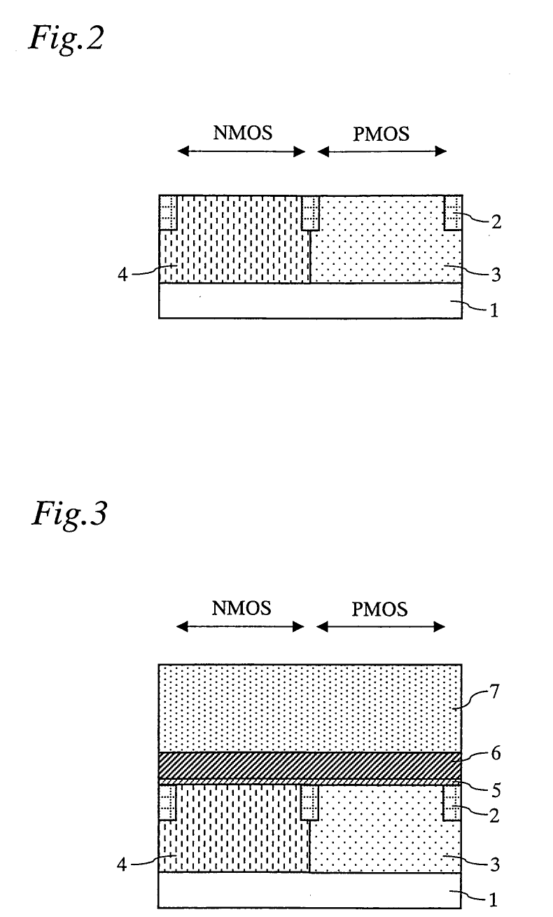

FIGS. 2 to 17 show a method for manufacturing a semiconductor device according to the present invention. It should be noted that in these figures, components which are the same as those in FIG. 1 are denoted by like numerals.

First of all, the device separation regions 2 are formed in predetermined regions of the surface of the silicon substrate 1 such that they define the NMOS and the PMOS regions, as shown in FIG. 2. Then, the N well 3 and the P well 4 are formed in the PMOS and the NMOS regions, respectively.

After implanting impurities for threshold voltage adjustment into the N well 3 and the P well 4, the gate insulating film 5 is formed on the silicon substrate 1, as shown in FIG. 3.

The gate insulating film 5 may be formed as follows. First, the surface of the silicon substrate 1 is oxidized under an atmosphere of an oxidizing gas at approximately 850° C. to produce an SiO₂ film (a silicon oxide film) having a film thickness of approximately 2.0 nm. Then, the surface of this SiO₂ film is nitrided under an atmosphere of NO (nitrogen monoxide) gas, and the resultant nitrided film is used as the gate insulating film 5. Or alternatively, a film of Al₂O₃ (alumina), HfO₂ (hafnium oxide), or ZrO₂ (zirconium oxide) or a mixture thereof may be formed to have a film thickness of approximately 3.0-5.0 nm and used as the insulating film 5.

Then, a polysilicon film 6 is formed on the gate insulating film 5 as a first material film. It should be noted that the first material film is not limited to polysilicon films. Any film made of either intrinsic silicon or a material having a work function equivalent to that of intrinsic silicon may be used.

The polysilicon film 6 may be formed by, for example, an LPCVD (Low Pressure Chemical Vapor Deposition) technique using SiH₄ (silane) or SiD₄ as a raw material. The film thickness of the polysilicon film 6 may be set to, for example, approximately 20 nm.

After forming the polysilicon film 6, an SiO₂ film 7 is formed on it as a hard mask material, as shown in FIG. 3. For example, an SiO₂ film (7) having a film thickness of approximately 100 nm may be formed by an LPCVD technique using TEOS (tetraethoxysilane) as a raw material.

After forming the SiO₂ film 7, an antireflective film (not shown) may be formed on it. When the resist film subsequently formed on the antireflective film is patterned, the antireflective film absorbs the exposure light which has passed through the resist film, functioning to eliminate the reflection of the exposure light at the interface between the resist film and the antireflective film. A film predominantly made of an organic substance and formed by, for example, the spin coat method, etc. may be used as the antireflective film.

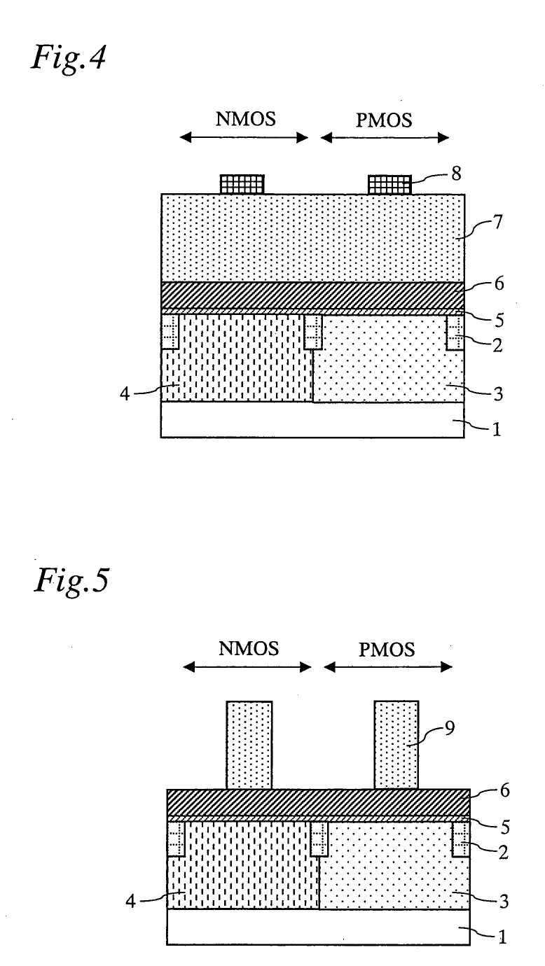

Then, a resist film (not shown) is formed on the SiO₂ film 7, and resist patterns 8 having a desired line width are formed by a photolithographic technique, producing the structure shown in FIG. 4. The resist patterns 8 correspond to the gate electrode patterns.

Then, the SiO₂ film 7 is dry-etched using the resist patterns 8 as masks. After that, the resist patterns 8, which are no longer necessary, are removed, producing SiO₂ film patterns 9 which act as hard masks, as shown in FIG. 5.

Then, the polysilicon film 6 is dry-etched using the SiO₂ film patterns 9 as masks to produce the gate electrode patterns. The etching gas may consist of one or more types of gases selected from a group consisting of BCl₃, Cl₂, HBr, CF₄, O₂, Ar, N₂, and He, for example.

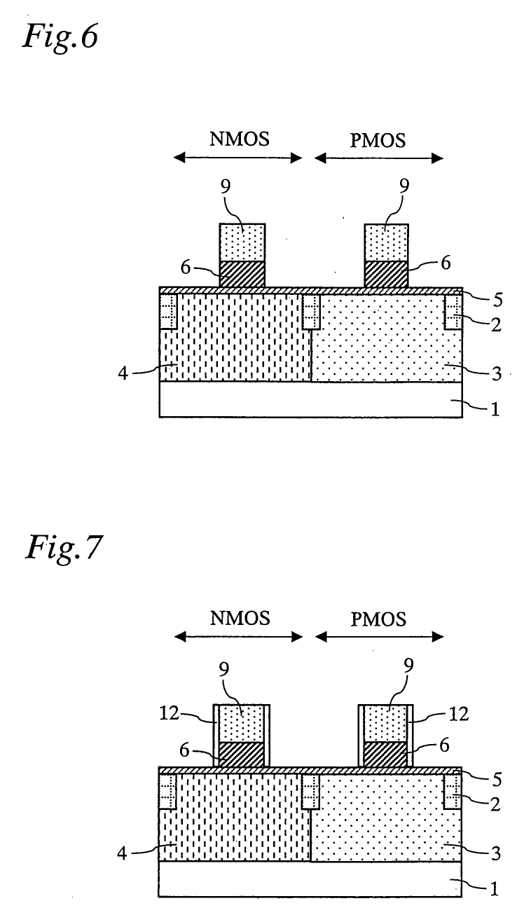

FIG. 6 shows the state of the components immediately after the polysilicon film 6 is dry-etched. As shown in FIG. 6, the polysilicon film 6 has been etched to produce the gate electrode patterns in the NMOS and the PMOS regions.

It should be noted that the gate electrode patterns (the polysilicon film 6) must be further processed before they can be used as complete gate electrodes of a semiconductor device product. That is, the present embodiment is characterized in that after forming the gate electrode patterns made of the polysilicon film 6 in the NMOS and the PMOS regions at the same time, gate electrodes each made of a material having a different work function are formed in these regions, respectively, in a process described later. This arrangement can manufacture the device using a smaller number of processes than in conventional methods in which gate electrodes each having a different work function are formed in the NMOS and the PMOS regions separately.

Then, an SiO₂ film 12 is formed on the sidewalls of the polysilicon film (patterns) 6 and the SiO₂ film patterns 9, producing the structure shown in FIG. 7. The film thickness of the SiO₂ film 12 may be set to, for example, approximately 2.0 nm. For example, the SiO₂ film 12 may be formed through oxidation under an atmosphere of an oxidizing gas at approximately 850° C. Or it may be formed by an LPCVD technique using TEOS as a raw material.

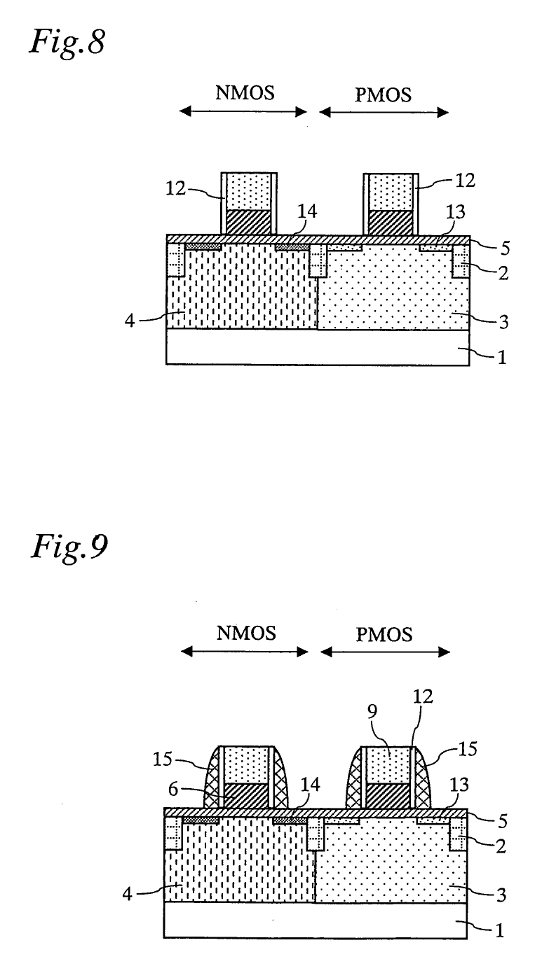

After forming the SiO₂ film 12, LDD (Lightly Doped Drain) regions, which are shallow lightly doped drain layers, are formed. Specifically, P type or N type impurities are implanted in the silicon substrate 1 using as masks the polysilicon film (patterns) 6 and the SiO₂ film patterns 9 each having the SiO₂ film 12 formed on its sidewalls. This process can form LDD regions 13 and 14 in the PMOS and the NMOS regions, respectively, as shown in FIG. 8.

Then, an SiN (silicon nitride) film is formed on the entire surface by an LPCVD technique, etc. and then etched back to form sidewall spacers 15 on the SiO₂ film 12 formed on the sidewalls of the polysilicon film (patterns) 6 and the SiO₂ film patterns 9, as shown in FIG. 9.

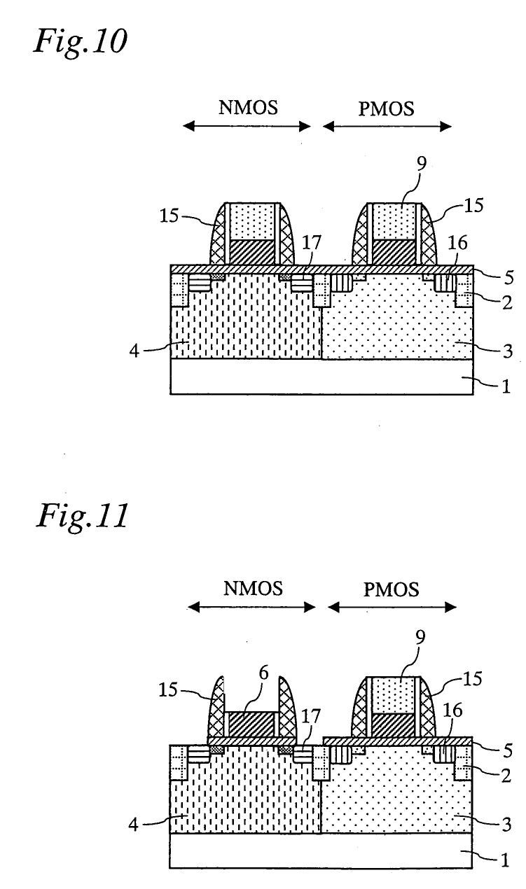

After forming the sidewall spacers 15, impurities are ion-implanted in the silicon substrate 1 using as masks the polysilicon film (patterns) 6 and the SiO₂ film patterns 9 (and sidewall spacers 15). Specifically, P type impurities are implanted in the silicon substrate 1 in the PMOS region to form the PMOS source/drain region 16, and N type impurities are implanted in the silicon substrate 1 in the NMOS region to form the NMOS source/drain region 17, as shown in FIG. 10. Then, the impurities in the N and P wells 3 and 4, the LDD regions 13 and 14, and the source/drain regions 16 and 17 are activated through heat treatment.

Then, the SiO₂ film pattern 9 in the NMOS region and the portion of the gate insulating film 5 on the NMOS source/drain region 17 are removed, producing a structure in which the polysilicon film (pattern) 6 and the silicon constituting the source/drain region 17 in the NMOS region are exposed, as shown in FIG. 11.

For example, after forming a resist pattern having openings on the SiO₂ film pattern 9 and above the source/drain region 17 in the NMOS region, the substrate is dipped in an etching solution containing HF (hydrogen fluoride). This process can remove the SiO₂ film pattern 9 and the portions of the gate insulating film 5 exposed at the openings. Then, the resist pattern is removed since it is no longer necessary, producing the structure shown in FIG. 11. It should be noted that this process is not limited to wet etching using HF. The SiO₂ film pattern 9 and the portions of the gate insulating film 5 may be removed by dry etching.

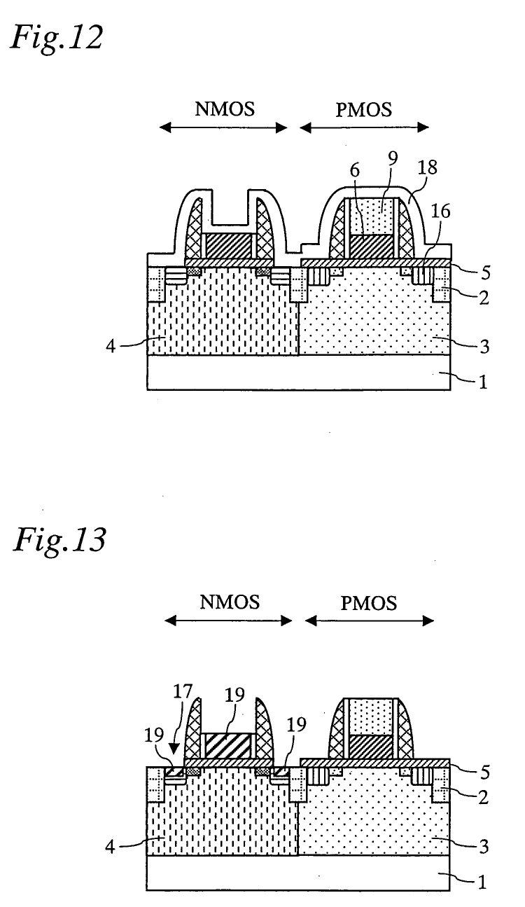

Then, a Ti (titanium) film is formed on at least the polysilicon film (pattern) 6 and the source/drain region 17 in the NMOS region as a second material film. In the example shown in FIG. 12, a Ti film 18 is formed on the entire surface of the substrate. The film thickness of the Ti film may be set to, for example, approximately 10 nm.

Instead of the Ti film, any other film made of a material having a work function smaller than that of intrinsic silicon may be used as the second material film. For example, the second material film may be a Hf (hafnium) film, Zr (zirconium) film, Al (aluminum) film, Nb (niobium) film, Ta (tantalum) film, V (vanadium) film, or TaN (tantalum nitride) film.

According to the present embodiment, a TiN (titanium nitride) film may be additionally formed on the Ti film 18 in FIG. 12.

After forming the Ti film 18, a heat treatment is carried out to cause the polysilicon film (pattern) 6 in the NMOS region and part of the silicon constituting the source/drain region 17 to selectively react with the Ti film 18. For example, the substrate may be heat treated at 650° C. under a nitrogen atmosphere for 30 seconds. In the example shown in FIG. 12, the polysilicon film (pattern) 6 and the source/drain region 16 in the PMOS region are covered with the SiO₂ film pattern 9 and the gate insulating film 5, respectively. Therefore, the polysilicon film (pattern) 6 and the silicon constituting the source/drain region 16 in the PMOS region do not react with the Ti film 18.

After the heat treatment, the unreacted portion of the Ti film 18 is removed, producing the structure shown in FIG. 13. Specifically, the substrate may be dipped in a solution of H₂SO₄ (sulfuric acid) and H₂O₂ (hydrogen peroxide) to remove the unreacted portion of the Ti film 18. It should be noted that at that time, if the Ti film 18 has a TiN film formed thereon, this TiN film can also be removed, together with the Ti film 18.

The above process can form a gate electrode made up of a TiSiₓ (titanium silicide) film 19, which is a reaction film between the polysilicon film 6 and the Ti film 8, in the NMOS region. At the same time, the above process also can form another TiSiₓ film 19 in the source/drain region 17 in the NMOS region. That is, a silicide layer can be formed in the source/drain region 17 so as to reduce the resistance of this region and thereby increase the current driving capability of the transistor. After that, the substrate may be heat treated, for example, at 800° C. under a nitrogen atmosphere for 30 seconds to reduce the resistance of the TiSiₓ films 19.

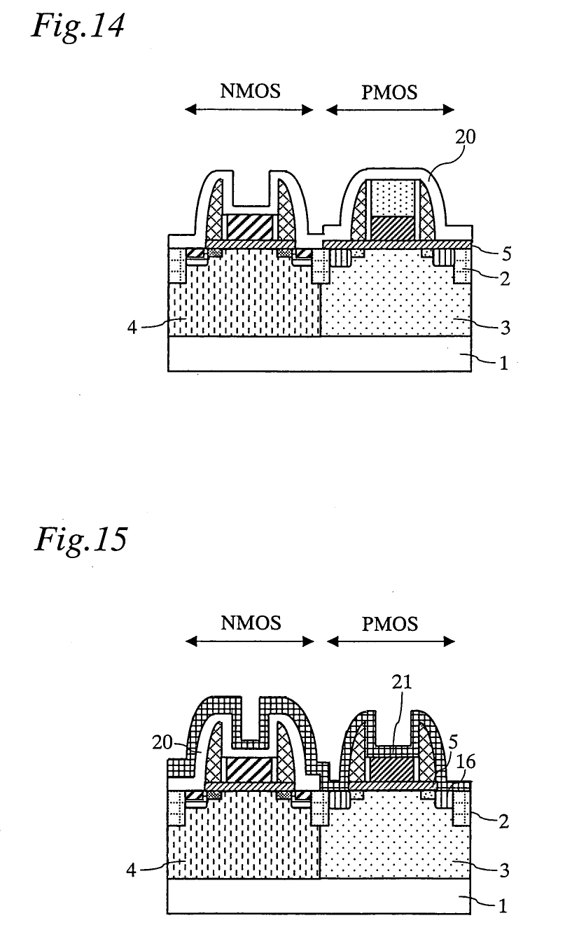

Then, an SiO₂ film 20 is formed on the entire surface of the substrate, as shown in FIG. 14. This may be done by, for example, an LPCVD technique using TEOS as a raw material.

Then, the portion of the SiO₂ film 20 and the polysilicon film pattern 9 in the PMOS region and the portion of the gate insulating film 5 on the source/drain region 16 are removed. After that, a Ni (nickel) film is formed on at least the polysilicon film (pattern) 6 and the source/drain region 16 in the PMOS region as a third material film. In the example shown in FIG. 15, a Ni film 21 is formed on the entire surface of the substrate. The film thickness of the Ni film 21 may be set to, for example, approximately 10 nm.

Instead of the Ni film 21, any other film made of a material having a work function larger than that of intrinsic silicon may be used as the third material film. For example, the third material film may be a Pt (platinum) film, Ir (iridium) film, Re (rhenium) film, or RuO₂ (ruthenium oxide) film.

According to the present embodiment, a TiN film may be additionally formed on the Ni film 21 in FIG. 15.

After forming the Ni film 21, a heat treatment is carried out to cause the polysilicon film (pattern) 6 in the PMOS region and part of the silicon constituting the source/drain region 16 to selectively react with the Ni film 21. For example, the substrate may be heat treated at 500° C. under a nitrogen atmosphere for 30 seconds.

In the example shown in FIG. 15, the NMOS region is covered with the SiO₂ film 20. Therefore, it is possible to cause the polysilicon film (pattern) 6 in the PMOS region and the silicon constituting the source/drain region 16 to selectively react with the Ni film 21.

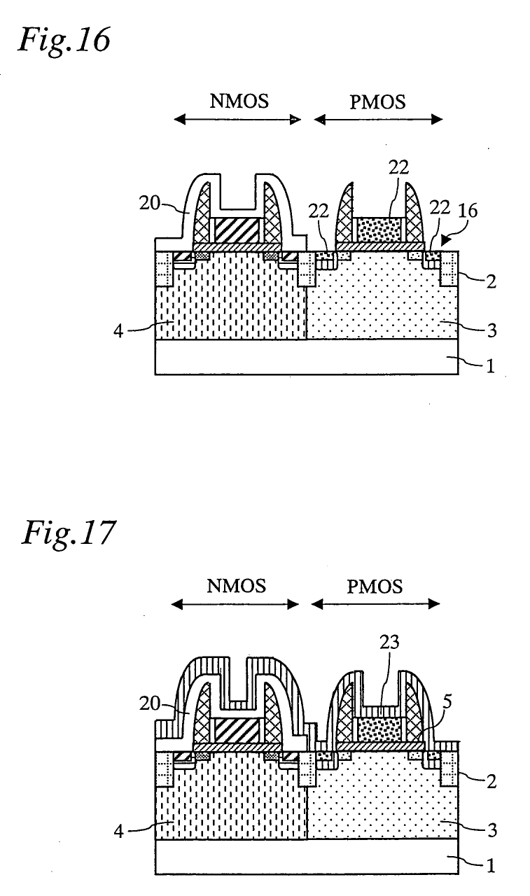

After the heat treatment, the unreacted portion of the Ni film 21 is removed, producing the structure shown in FIG. 16. Specifically, the substrate may be dipped in a solution of HNO₃ (nitric acid), or H₂SO₄ (sulfuric acid), and H₂O₂ (hydrogen peroxide) to remove the unreacted portion of the Ni film 21. It should be noted that at that time, if the Ni film 21 has a TiN film formed thereon, this TiN film can also be removed, together with the Ni film 21.

The above process can form a gate electrode made up of an NiSiₓ (nickel silicide) film 22, which is a reaction film between the polysilicon film 6 and the Ni film 21, in the PMOS region. At the same time, the above process also can form another NiSiₓ film 22 in the source/drain region 16 in the PMOS region. That is, a silicide layer can be formed in the source/drain region 16 so as to reduce the resistance of this region and thereby increase the current driving capability of the transistor.

After forming the SiNi film 22, an SiO₂ film 23 is formed on the entire surface of the substrate, producing the structure shown in FIG. 17.

Thus, a CMOS transistor can be formed.

If the second material film and the third material film consist of metal and the formed metal silicides are represented by M₂Si (M: metal), the thickness of these material films prefer to more than two times the thickness of silicon. In case the metal silicides are represented by MSi, the thickness of these material films prefer to more than the thickness of silicon. And in case the metal silicides are represented by MSi₂, the thickness of these material films prefer to more than a half time of the thickness of silicon.

According to the present embodiment, a semiconductor device comprises: an NMOS region including a first gate electrode and a first source/drain region; and a PMOS region including a second gate electrode and a second source/drain region; wherein the first gate electrode in the NMOS region is made of either intrinsic silicon or a material having a work function equivalent to that of intrinsic silicon, and a material having a work function smaller than that of intrinsic silicon; and wherein the second gate electrode in the PMOS region is made of either intrinsic silicon or a material having a work function equivalent to that of intrinsic silicon, and a material having a work function larger than that of intrinsic silicon. With this arrangement, the work functions of the NMOS and the PMOS gate electrodes (the first and second gate electrodes) can be set to 4.0-4.5 eV and 4.5-5.2 eV, respectively, making it possible to reduce the threshold voltages of the NMOS and PMOS transistors to 0.5 V or less.

Further, the present embodiment can form silicide layers in the source/drain regions when forming the gate electrodes. Therefore, the present embodiment can manufacture a semiconductor device more easily than conventional methods in which gate electrode forming process and the silicide layer forming process are performed separately and the source/drain regions are silicided in such a way that no silicide layers are formed on the gate electrodes.

Still further, the present embodiment can manufacture a semiconductor device using a smaller number of processes than in conventional methods in which the NMOS and PMOS gate electrodes are formed separately, resulting in increased yield and throughput and hence reduced cost.

As described above, the present embodiment forms silicide layers in the source/drain regions. However, according to the present invention, no silicide layers may be formed. For example, in FIG. 11, if the gate insulating film 5 on the source drain region 17 is not removed, the silicon constituting the source/drain region 17 can be prevented from reacting with the Ti film 18, eliminating the need for forming a silicide layer in the source/drain region 17. Likewise, in FIG. 15, if the gate insulating film 5 on the source/drain region 16 is not removed, the silicon constituting the source/drain region 16 can be prevented from reacting with the Ni film 21, eliminating the need for forming a silicide layer in the source/drain region 16.

The features and advantages of the present invention may be summarized as follows.

As described above, a semiconductor device of the present invention comprises: an NMOS region including a first gate electrode and a first source/drain region; and a PMOS region including a second gate electrode and a second source/drain region; wherein the first gate electrode in the NMOS region is formed of either intrinsic silicon or a material having a work function equivalent to that of intrinsic silicon, and a material having a work function smaller than that of intrinsic silicon; and wherein the second gate electrode in the PMOS region is formed of either intrinsic silicon or a material having a work function equivalent to that of intrinsic silicon, and a material having a work function larger than that of intrinsic silicon. With this arrangement, the work functions of the NMOS and the PMOS gate electrodes (the first and second gate electrodes) can be set to 4.0-4.5 eV and 4.5-5.2 eV, respectively, making it possible to reduce the threshold voltages of the NMOS and PMOS transistors to 0.5 V or less.

Further, the present invention forms silicide layers in both the NMOS and the PMOS source/drain regions so as to reduce the resistance of these regions and thereby increase the current driving capability of the transistors.

Still further, the present invention can manufacture a semiconductor device using a smaller number of processes than in conventional methods in which the NMOS and the PMOS gate electrodes are formed separately from each other, resulting in increased yield and throughput and hence reduced cost.

Still further, the present invention can form silicide layers in the source/drain regions when forming the gate electrodes, making it possible to easily manufacture a semiconductor device.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2003-315743, filed on Sep. 8, 2003 including specification, claims, drawings and summary, on which the Convention priority of the present application is based, are incorporated herein by reference in its entirety.

1. A semiconductor device comprising:
an NMOS region including a first gate electrode and a first source/drain region; and
a PMOS region including a second gate electrode and a second source/drain region, wherein
said first gate electrode in said NMOS region is one of intrinsic silicon and a material having a work function equivalent to that of intrinsic silicon, and a material having a work function smaller than that of intrinsic silicon; and
said second gate electrode in said PMOS region is one of intrinsic silicon and a material having a work function equivalent to that of intrinsic silicon, and a material having a work function larger than that of intrinsic silicon.

2. The semiconductor device according to claim 1, wherein:
said first source/drain region in said NMOS region includes a silicide layer of a material having a work function smaller than that of intrinsic silicon; and
said second source/drain region in said PMOS region includes a silicide layer of a material having a work function larger than that of intrinsic silicon.

3. The semiconductor device according to claim 1, wherein said material having a work function smaller than that of intrinsic silicon is selected from the group consisting of titanium, hafnium, zirconium, aluminum, niobium, tantalum, vanadium, and tantalum nitride.

4. The semiconductor device according to claim 1, wherein said material having a work function larger than that of intrinsic silicon is selected from the group consisting of nickel, platinum, iridium, rhenium, and ruthenium dioxide.

5. A method for manufacturing a semiconductor device, comprising:
forming a device separation region in a silicon substrate to define an NMOS region and a PMOS region;
forming a gate insulating film on said silicon substrate;
forming a first material film on said gate insulating film, said first material film being one of intrinsic silicon and a material having a work function equivalent to that of intrinsic silicon;
etching said first material film to form a gate electrode pattern;
forming a second material film on at least the portion of said first material film in said NMOS region, said second material film being a material having a work function smaller than that of intrinsic silicon;
selectively reacting, by heating, said second material film with said first material film to form an NMOS gate electrode including a first reaction film between said first material film and said second material film;
removing an unreacted portion of said second material film;
forming a third material film on at least the portion of said first material film in said PMOS region, said third material film being a material having a work function larger than that of intrinsic silicon;
selectively reacting, by heating, said third material film with said first material film to form a PMOS gate electrode including a second reaction film between said first material film and said third material film; and
removing an unreacted portion of said third material film.

6. The method for manufacturing a semiconductor device according to claim 5, wherein:
forming said second material film includes forming said second material film on a source/drain region in said NMOS region;
forming said NMOS gate electrode includes reacting said second material film with silicon constituting said source/drain region in said NMOS region to form a silicide layer in said source/drain region in said NMOS region;
forming said third material film includes forming said third material film on a source/drain region in said PMOS region); and
forming said PMOS gate electrode includes reacting said third material film with silicon constituting said source/drain region in said PMOS region to form a silicide layer in said source/drain region in said PMOS region.
